(19) United States
(12) Patent Application Publication
(10) Pub. No.: US 2021/0082856 A1
(43) Pub. Date: Mar. 18, 2021

(54) SEMICONDUCTOR DEVICE AND MANUFACTURING METHOD THEREOF

(71) Applicant: Kioxia Corporation, Minato-ku (JP)

(72) Inventor: Soichi HOMMA, Yokkaichi (JP)

(73) Assignee: Kioxia Corporation, Minato-ku (JP)

(21) Appl. No.: 16/909,171

(22) Filed: Jun. 23, 2020

(30) Foreign Application Priority Data
Sep. 12, 2019 (JP) 2019-166283

(51) Int. Cl. H01L 23/00; H01L 25/18; H01L 25/00

(52) U.S. Cl. CPC H01L 24/17; H01L 2224/81011; H01L 24/11; H01L 24/73; H01L 24/81; H01L 25/50; H01L 24/92; H01L 2224/17517; H01L 2224/17152; H01L 2224/73253; H01L 2224/17505; H01L 2924/3511; H01L 2224/11618; H01L 2224/81207; H01L 2224/81208; H01L 2224/92225; H01L 25/18

(57) ABSTRACT

A semiconductor device according to an embodiment of the present invention comprises pads electrically connected to wires provided on an insulating substrate. A wiring substrate comprises a first insulant provided between the pads. A first semiconductor chip comprises metal bumps respectively connected to the pads on the wiring substrate on a first face facing the wiring substrate. A first adhesion layer is provided between the first insulant and the first semiconductor chip and adheres the wiring substrate and the first semiconductor chip to each other. An insulating resin is provided to cover peripheries of the first adhesion layer and the metal bumps between the wiring substrate and the first semiconductor chip, and a structure on the wiring substrate.

### CROSS REFERENCE TO RELATED APPLICATIONS

This application is based upon and claims the benefit of priority from the prior Japanese Patent Application No. 2019-166283, filed on Sep. 12, 2019, the entire contents of which are incorporated herein by reference.

### FIELD

The embodiments of the present invention relate to a semiconductor device and manufacturing method thereof.

### BACKGROUND

Semiconductor chips have metal bumps and are flip-chip connected to a terminal on a wiring substrate in some cases. Further, semiconductor chips are thinned and sometimes warp after a manufacturing process of semiconductor elements. If such a warped semiconductor chip is flip-chip connected onto a wiring substrate, the semiconductor chip may chip or cause poor connection between the metal bumps and the terminal of the wiring substrate. In a case in which an underfill resin is filled between a semiconductor chip and a wiring substrate, the underfill resin creeps up on the semiconductor chip when the semiconductor chip is thin, and the semiconductor chip has a probability of breaking when another semiconductor chip is stacked thereon.

### BRIEF DESCRIPTION OF THE DRAWINGS

FIGS. 1A and 1B are sectional views illustrating a configuration example of a semiconductor device according to a first embodiment;

FIGS. 2A and 2B are sectional views illustrating a configuration example of the first adhesion layers and the periphery thereof;

FIGS. 3A to 7C are sectional views illustrating an example of a manufacturing method of the controller chip according to the first embodiment;

FIGS. 8A to 9B are sectional views illustrating an example of an assembly process for mounting the controller chip on the wiring substrate;

FIGS. 10A and 10B are plan views illustrating a layout of the metal bumps and the first adhesion layers on the second face of the controller chip; and

FIG. 11 is a sectional view illustrating a configuration example of the controller chip according to a third modification.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor device according to an embodiment of the present invention comprises pads electrically connected to wires provided on an insulating substrate. A wiring substrate comprises a first insulant provided between the pads. A first semiconductor chip comprises metal bumps respectively connected to the pads on the wiring substrate on a first face facing the wiring substrate. A first adhesion layer is provided between the first insulant and the first semiconductor chip and adheres the wiring substrate and the first semiconductor chip to each other. An insulating resin is provided to cover peripheries of the first adhesion layer and the metal bumps between the wiring substrate and the first semiconductor chip, and a structure on the wiring substrate.

### First Embodiment

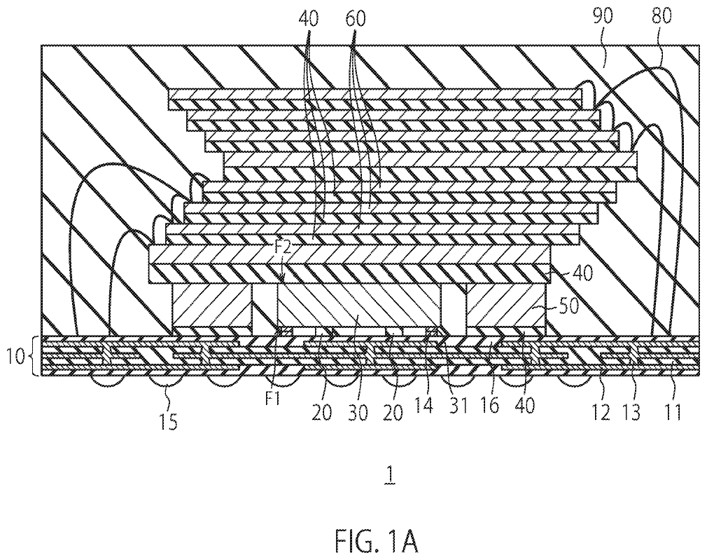

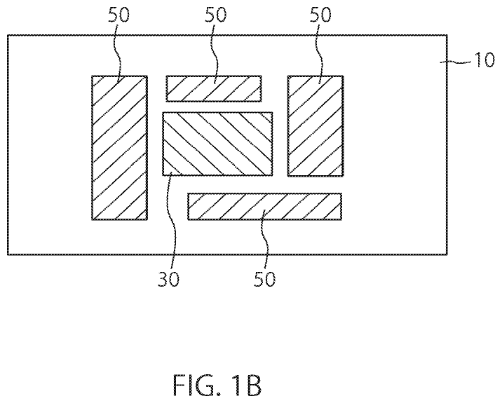

FIG. 1A is a sectional view illustrating a configuration example of a semiconductor device according to a first embodiment. A semiconductor device 1 according to the present embodiment is, for example, a NAND flash memory. The semiconductor device 1 includes a wiring substrate 10, first adhesion layers 20, a controller chip 30, a second adhesion layer (DAF (Die Attach Film)) 40, spacers 50, a NAND memory chip (hereinafter, “memory chip”) 60, bonding wires 80, and a sealing resin 90. The sealing resin 90 is so-called a molding resin. The present embodiment is applicable to any semiconductor device to be flip-chip connected, without being limited to a NAND flash memory.

The wiring substrate 10 includes an insulating substrate 11, wires 12, contact plugs 13, metal pads 14, solder balls 15, and a solder resist 16 serving as a first insulant. For example, an insulating material such as a glass epoxy resin or a ceramic is used as the insulating substrate 11. The wires 12 are provided on the front or rear surface of the insulating substrate 11 or in the inner portion thereof and electrically connect the metal pads 14 to the solder balls 15. The contact plugs 13 are provided to penetrate through the insulating substrate 11 and electrically connect the wires 12 to each other. The metal pads 14 are connected to metal bumps 31 of the controller chip 30 on the front surface of the wiring substrate 10. The solder balls 15 are connected to the wires 12 on the rear surface of the wiring substrate 10. For example, a single film, a composite film, or an alloy film of conducting materials such as Al, Cu, Au, Ni, Pd, and Ag is used as the wires 12, the contact plugs 13, and the metal pads 14. For example, a conducting material such as a single film, a composite film, or an alloy film of Sn, Ag, Cu, Au, Bi, Zn, In, Sb, Ni, and the like is used as the solder balls 15. The solder resist 16 serving as the first insulant is provided on the front and rear surfaces of the wiring substrate 10 and is provided between adjacent ones of the metal pads 14 or between adjacent ones of the solder balls 15 to electrically insulate the metal pads 14 or the solder balls 15 from each other. The solder resist 16 as the first insulant coats the front surfaces of the wires 12 to protect the wires 12.

The controller chip 30 serving as a first semiconductor chip has a first face F1 facing the wiring substrate 10 and a second face F2 on the opposite side to the first face F1. The metal bumps 31 are provided on the first face F1. The meal bumps 31 are connected (welded) to the metal pads 14 of the wiring substrate 10. That is, the controller chip 30 is flip-chip connected onto the wiring substrate 10. For example, a conducting metal such as solder is used as the metal bumps 31.

The controller chip 30 is thin and has semiconductor elements on the first face F1 or the second face F2. The controller chip 30 sometimes warps during formation of the semiconductor elements. The warp of the controller chip 30 can be, for example, mountain-shaped, bowl-shaped, or saddle-shaped. The warp of the controller chip 30 is not illustrated in FIG. 1A.

First adhesion layers 20 that have column shape are provided on the first face F1 of the controller chip 30. A plurality of the first adhesion layers 20 may be provided on the first face F1. The first adhesion layers 20 may respectively have a cylindrical shape or a prismatic shape, or may have an irregular cross section when it is cut in parallel with the first face F1. When the controller chip 30 is stacked on the wiring substrate 10, the first adhesion layers 20 are provided between the wiring substrate 10 and the first face F1 of the controller chip 30 and adhere the wiring substrate 10 and the controller chip 30 to each other.

In the present embodiment, an NCP (Non Conductive Paste) layer or an NCF (Non Conductive Film) layer that fills a space between the wiring substrate 10 and the first face F1 of the controller chip 30 is not provided. However, the first adhesion layers 20 adhere the wiring substrate 10 and the controller chip 30 to each other, instead of the NCP layer or the NCF layer. Accordingly, the first adhesion layers 20 support connection between the metal pads 14 and the metal bumps 31 and suppress fracture between the metal pads 14 and the metal bumps 31. Since the controller chip 30 and the wiring substrate 10 are adhered by the first adhesion layers 20, warp of the controller chip 30 reduces.

The spacers 50 served as supporting members have back surfaces (the third surfaces) facing the wiring substrate 10 and top surfaces (the fourth surfaces) opposing to the third surfaces. The spacers 50 are provided around the controller chip 30. The back surfaces of the spacers 50 are adhered onto the wiring substrate 10 by the DAF 40 serving as the second adhesion layer on the back surface of the spacers 50. The other second adhesion layers 40 are formed on top surfaces of the spacers 50 to adhere the memory chip 60 to the spacers 50. The spacers 50 are provided up to a substantially equal level to that of the second face F2 of the controller chip 30 and support the memory chip 60. The spacers 50 have, for example, a rectangular frame shape or a shape surrounding the controller chip 30 with rectangles and are provided to surround the controller chip 30 in four directions on the front surface of the wiring substrate 10. For example, a material such as silicon, glass, an insulating substrate, or a metallic plate is used as the spacers 50. In order to improve the adhesion property, an organic film of a polyimide resin, a polyamide resin, an epoxy resin, an acrylic resin, a phenolic resin, a silicon resin, a PBO (PolyBenzOxazole) resin, or the like may be formed on the spacers 50.

The memory chip 60 is provided above the controller chip 30 and are adhered to the controller chip 30 and on the fourth surfaces of the spacers 50 by the second adhesion layer (DAF) 40. The memory chip 60 has, for example, a three-dimensional memory cell array where a plurality of memory cells are three-dimensionally arranged. The second adhesion layer (DAF) 40 is provided on the second face F2 of the controller chip 30 and the spacers 50 and adheres the memory chip 60 onto the controller chip 30 and the spacers 50.

A plurality of the second adhesion layers (DAFs) 40 and a plurality of the memory chips 60 may alternately be stacked on the controller chip 30 and the spacers 50. Even when the memory chips 60 are thus stacked above the controller chip 30, the memory chips 60 are less likely to be affected by warp of the controller chip 30 because the warp of the controller chip 30 is reduced. That is, the memory chips 60 are less likely to chip and are less likely to be peeled off from the second adhesion layers (DAFs) 40.

The bonding wires 80 electrically connect metal pads 70 of the memory chips 60 to any of the metal pads 14 of the wiring substrate 10. The sealing resin 90 serving as an insulating resin coats the entire structure on the wiring substrate 10, such as the controller chip 30, the memory chips 60, and the bonding wires 80, for protection. The sealing resin 90 is filled between the wiring substrate 10 and the first face F1 of the controller chip 30 and is placed to coat the peripheries of the first adhesion layers 20 and the metal bumps 31.

Here, the first adhesion layers 20 are described in detail.

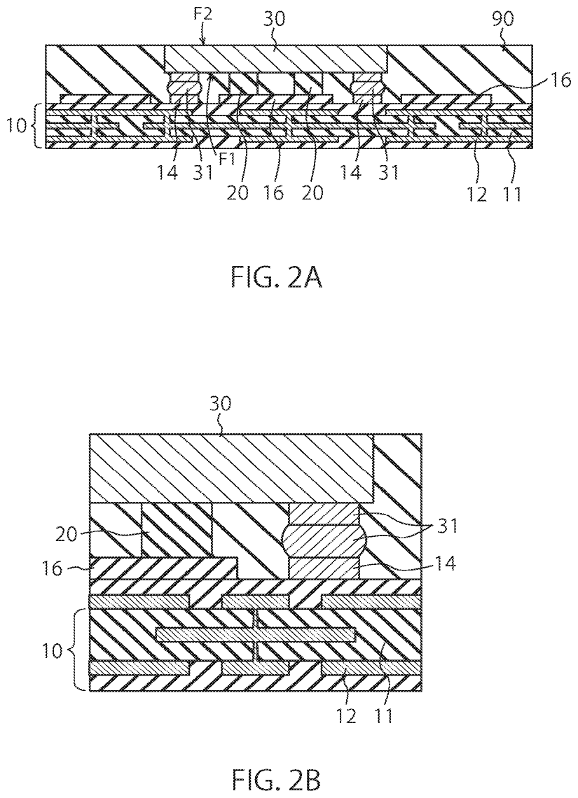

FIGS. 2A and 2B are sectional views illustrating a configuration example of the first adhesion layers 20 and the periphery thereof. The first adhesion layers 20 are provided between the first face F1 of the controller chip 30 and the solder resist 16 serving as the first insulant of the wiring substrate 10 and adhere the controller chip 30 and the wiring substrate 10 to each other. The thermal expansion coefficient of the first adhesion layers 20 is larger than those of the wiring substrate (for example, a glass epoxy resin) 10, the controller chip (for example, silicon) 30, and the sealing resin 90. The thermal expansion coefficient of the controller chip (for example, silicon) 30 is smaller than that of the wiring substrate (for example, the glass epoxy resin) 10. Therefore, when the controller chip 30 is mounted on the wiring substrate 10, the wiring substrate 10 more greatly expands or contracts than the controller chip 30 depending on temperatures. For example, the thermal expansion coefficient of silicon monocrystal is about 3.5 ppm/° C. and the thermal expansion coefficient of the glass epoxy resin is about 17 ppm/° C. Therefore, when the thermal expansion coefficient of the first adhesion layers 20 is smaller than those of the wiring substrate 10 and the controller chip 30, the first adhesion layers 20 cannot follow the expansion/contraction difference between the wiring substrate 10 and the controller chip 30 and have a risk of being peeled off when the controller chip 30 is mounted on the wiring substrate 10. Accordingly, it is preferable that the thermal expansion coefficient of the first adhesion layers 20 is in a range from 20 ppm/° C. to 100 ppm/° C. More preferably, the thermal expansion coefficient of the first adhesion layers 20 is in a range from 30 ppm/° C. to 60 ppm/° C. If the thermal expansion coefficient of the first adhesion layers 20 is smaller than 20 ppm/° C., the thermal expansion coefficient is close to that of the wiring substrate 10 and the first adhesion layers 20 cannot follow the expansion/contraction difference between the wiring substrate 10 and the controller chip 30 and are at the risk of being peeled off. If the thermal expansion coefficient of the first adhesion layers 20 is conversely larger than 100 ppm/° C., the first adhesion layers 20 expand too much and there is a risk that the controller chip 30 is peeled off from the wiring substrate 10. In these cases, the metal bumps 31 are broken or peeled off from the metal pads 14, which causes poor connection. Therefore, it is preferable that the thermal expansion coefficient of the first adhesion layers 20 is larger than those of the wiring substrate (for example, the glass epoxy resin) 10 and the controller chip (for example, silicon) 30. Further, the thermal expansion coefficient of the first adhesion layers 20 is preferably larger than that of the sealing resin 90, which enables suppression of warp.

Further, the elastic modulus of the first adhesion layers 20 is lower than those of the solder resist 16 serving as first insulant of the wiring substrate (for example, the glass epoxy resin) 10 and the metal bumps (for example, solder) 31. If the elastic modulus of the first adhesion layers 20 is higher (harder) than those of the solder resist 16 serving as the first insulant and the metal bumps 31, the first adhesion layers 20 have a risk of being peeled off without absorbing warp of the controller chip 30 with respect to the wiring substrate 10. Therefore, it is preferable that the elastic modulus of the first adhesion layers 20 is in a range from 1 megapascal to 3 gigapascals. More preferably, the elastic modulus of the first adhesion layers 20 is in a range from 10 megapascals to 1 gigapascal. If the elastic modulus of the first adhesion layers 20 is lower than 1 megapascal, the first adhesion layers 20 are too soft and it is difficult to fix the controller chip 30 to the wiring substrate 10. If the elastic modulus of the first adhesion layers 20 exceeds 3 gigapascals, the first adhesion layers 20 are too hard and have a risk of being peeled off from the controller chip 30 or the wiring substrate 10 due to warp of the controller chip 30. In these cases, the metal bumps 31 are broken or peeled off from the metal pads 14, which leads to poor connection. Therefore, it is preferable that the elastic modulus of the first adhesion layers 20 is lower than those of the solder resist 16 serving as the first insulant and the metal bumps (for example, solder) 31. Further, the elastic modulus of the first adhesion layers 20 is preferably lower than that of the sealing resin 90, which enables suppression of warp.

Accordingly, even if the controller chip 30 has warp, the first adhesion layers 20 adhere the controller chip 30 to the wiring substrate 10 and suppress the controller chip 30 from being peeled off from the wiring substrate 10. Further, the first adhesion layers 20 can straighten the warp of the controller chip 30 to some extent. Therefore, the metal bumps 31 and the metal pads 14 are enabled to be connected between the controller chip 30 and the wiring substrate 10 and the metal bumps 31 become less likely to be broken. As a result, poor connection between the metal bumps 31 and the metal pads 14 can be suppressed. Further, because the warp of the controller chip 30 is reduced, the memory chips 60 staked on the controller chip 30 can be suppressed from chipping.

As described above, according to the present embodiment, the first adhesion layers 20 are provided between the wiring substrate 10 and the controller chip 30 and reinforce connection between the metal bumps 31 and the metal pads 14 while straightening warp of the controller chip 30. Accordingly, even if the controller chip 30 has warp, the second face F2 of the controller chip 30 becomes close to a flat face. Therefore, even in a case in which the memory chips 60 are stacked above the controller chip 30, chip or poor adhesion of the memory chips 60 can be suppressed. Further, fracture of connection between the metal bumps 31 and the metal pads 14 between the wiring substrate 10 and the controller chip 30 can be suppressed.

In FIG. 1A, the controller chip 30 that is flip-chip connected and the memory chips 60 that are wire-bonded are both provided in a same semiconductor package. That is, a hybrid multi-chip package is illustrated in FIG. 1A. However, in the present embodiment, the memory chips 60 may also be flip-chip connected similarly to the controller chip 30. In this case, the controller chip 30 and the memory chips 60 may be electrically connected via a through silicon via (TSV). Although the insulating resin 90 is not provided on the controller chip 30 in FIGS. 2A and 2B, there may be the insulating resin 90 on the controller chip 30 in some cases such as a case in which another chip is not mounted on the controller chip 30.

Next, a manufacturing method of the semiconductor device 1 according to the present embodiment is described.

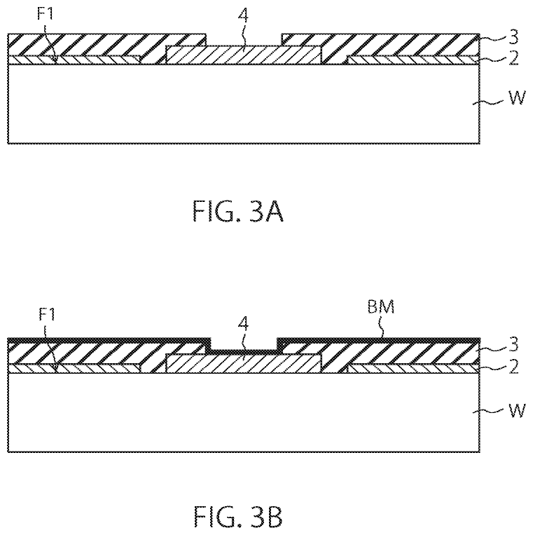

FIGS. 3A to 7C are sectional views illustrating an example of a manufacturing method of the controller chip 30 according to the first embodiment. First, semiconductor elements 2 and metal pads 4 are formed on a semiconductor substrate W as illustrated in FIG. 3A. The semiconductor substrate W is, for example, a semiconductor wafer of silicon, GaAs, SiC, or the like. The semiconductor elements 2 can be, for example, a CMOS (Complementary Metal Oxide Semiconductor) circuit. For example, a single film, a composite film, or an alloy film of Al, Cu, Au, Ni, Pd, Ag, and the like can be used as the metal pads 4.

Next, a protective insulating film 3 is formed so as to coat the semiconductor elements 2. The protective insulating film 3 is processed using a lithography technique and an etching technique to expose a part of the metal pads 4. For example, an insulating material such as a silicon oxide film, a silicon nitride film, a polyimide resin, a phenol resin, or a PBO (PolyBenzOxazole) resin is used as the protective insulating film 3. A composite film of these insulating materials may be used.

Next, a barrier metal BM is formed on the protective insulating film 3 and the metal pads 4 using a sputtering method, a vapor deposition method, a CVD (Chemical Vapor Deposition) method, an electroless plating method, or the like as illustrated in FIG. 3B. For example, a conducting metal such as titanium or copper is used as the barrier metal BM. A single film, a nitride film, a composite film, or an alloy film of Ti, Cr, Cu, Ni, Au, Pd, W, and the like may be used. For example, films of Ti and Cu are formed in this order by the sputtering method. For example, the film thickness of Ti is about 0.1 micrometer and the film thickness of Cu is about 0.3 micrometer.

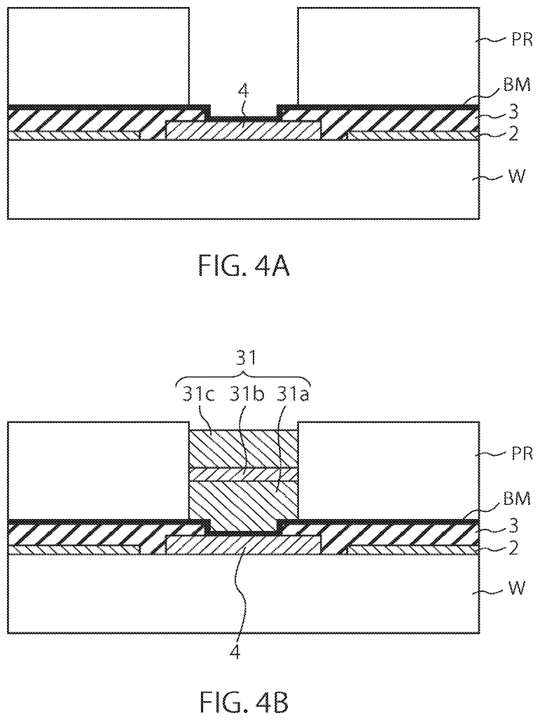

Next, a resist PR is formed on the barrier metal BM using a lithography technique as illustrated in FIG. 4A. The resist PR is patterned so as to open regions of the metal pads 4. The thickness of the resist PR is, for example, about 40 micrometers. The size of the opening is, for example, about 20 micrometers.

Subsequently, metal plating is performed to the barrier metal BM on the metal pads 4 as illustrated in FIG. 4B. For example, metals 31a, 31b, and 31c are formed on the barrier metal BM. For example, copper is used as the metal 31a. For example, nickel is used as the metal 31b. For example, solder (SnAg) is used as the metal 31c. The metals 31a to 31c function as the metal bumps 31. For example, a single film, a composite film, or an alloy film of Sn, Ag, Cu, Au, Bi, Zn, In, Sb, Ni, and the like can be used as the solder. The metal 31c may be formed using a printing method or a ball mounting method. The metal 31a is, for example, copper with a thickness of about 20 micrometers. The metal 31b is, for example, nickel with a thickness of about 3 micrometers. The metal 31c is, for example, SnAg with a thickness of about 12 micrometers.

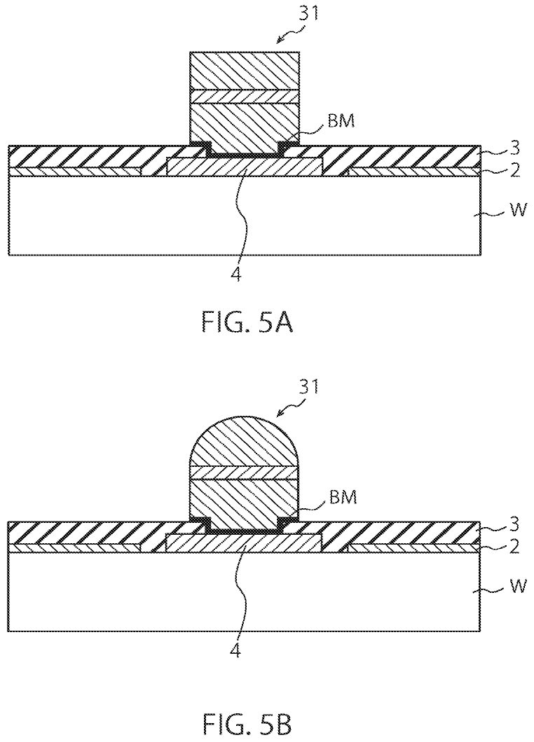

Next, after the resist PR is removed, the barrier metal BM is etched using the metal bumps 31 as a mask as illustrated in FIG. 5A. Accordingly, the barrier metal BM is left only under the metal bumps 31. For example, in a case in which copper is to be etched, a mixed liquid of citric acid and hydrogen peroxide can be used. In a case in which titanium is to be etched, hydrofluoric acid, a hydrogen peroxide solution, or the like can be used.

Subsequently, the metal 31c (for example, solder) of the metal bumps 31 is reflowed (melted) by thermal treatment to round the ends of the metal bumps 31 as illustrated in FIG. 5B. The reflow processing may be performed by applying flux and reflowing in an N₂ atmosphere, or may be performed by reflowing while reducing an oxide film of the solder in a reducing atmosphere such as formic acid gas, H₂ gas, or mixed gas of H₂ and N₂. The reflow processing may be performed by removing an oxide film of the solder with Ar plasma or the like. For example, after hydrosoluble flux is applied, the reflow is performed for 30 seconds in an N₂ atmosphere at 260° C.

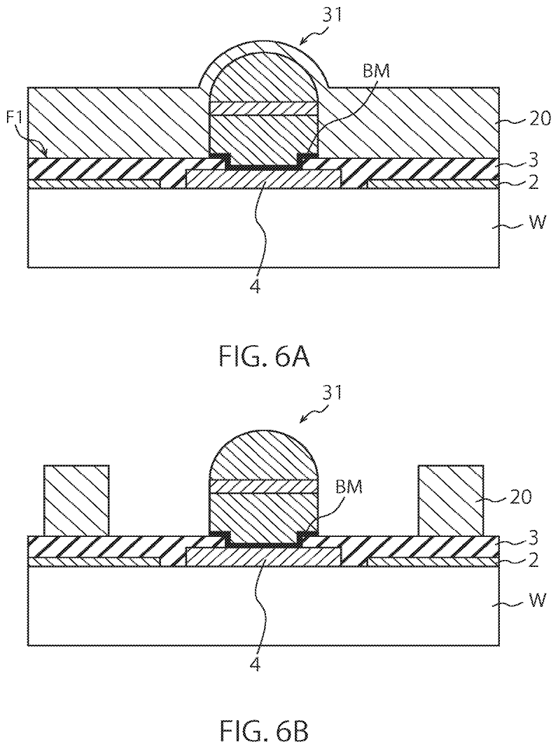

Next, a material of the photosensitive first adhesion layers 20 is applied onto the metal bumps 31 on the first face F1 and the protective insulating film 3 as illustrated in FIG. 6A. A photosensitive resin such as a phenol resin, a polyimide resin, a polyamide resin, an acrylic resin, an epoxy resin, a PBO resin, a silicon resin, or a benzocyclobutene resin, or a mixed material or a composite material thereof is used as the material of the first adhesion layers 20. For example, the material of the first adhesion layers 20 is applied with a film thickness (for example, about 20 micrometers) thinner than that of the metal bumps 31. Since the first adhesion layers 20 are the photosensitive material, the first adhesion layers 20 can be patterned using a lithography technique as illustrated in FIG. 6B. Accordingly, the first adhesion layers 20 are selectively formed in a columnar shape at predetermined positions on the protective insulating film 3. While the example in which the photosensitive first adhesion layers 20 are applied onto the controller chip 30 (the semiconductor chip) is illustrated, the first adhesion layers 20 may be formed on the wiring substrate 10 or may be formed on both the controller chip 30 and the wiring substrate 10.

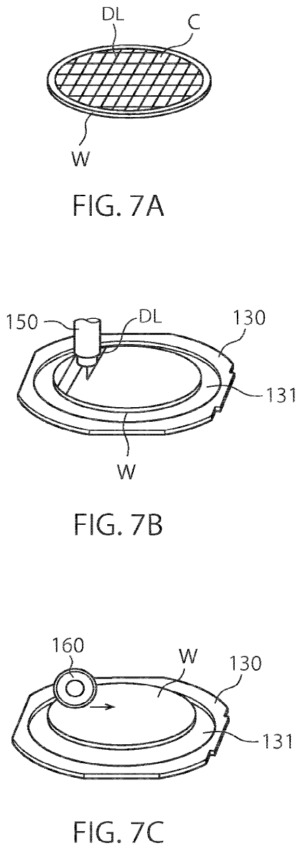

FIG. 7A illustrates a semiconductor wafer W having semiconductor elements formed thereon. The rear surface of the semiconductor wafer W is subsequently polished and thinned. There are dicing lines DL between a plurality of controller chips 30 and the controller chips 30 are singulated by cutting these dicing lines DL, which will be explained later.

Next, the semiconductor wafer W is attached to a flexible resin tape 131 stretched within a wafer ring 130 as illustrated in FIG. 7B. Next, portions corresponding to the dicing lines DL are irradiated with laser light from the front surface of the semiconductor wafer W using a laser oscillator 150. Accordingly, grooves are formed on the dicing lines DL of the semiconductor wafer W.

Subsequently, the dicing lines DL of the semiconductor wafer W are cut with a dicing blade 160 as illustrated in FIG. 7C. Accordingly, the semiconductor wafer W is separated into the controller chips 30 on the resin tape 131. The semiconductor wafer W may be separated only by blade dicing, without irradiation with laser light. Alternately, the semiconductor wafer W may be separated only by laser dicing.

Next, the resin tape 131 is irradiated with ultraviolet light to decrease the adhesion of an adhesive between the controller chip 30 and the resin tape 131 and enable removal of the controller chip 30 from the resin tape 131. A visual inspection and the like are also performed. The controller chips 30 are completed in this way. The memory chips 60 can be obtained, for example, by forming a memory cell array as the semiconductor element 2 on the semiconductor substrate W. Since other parts of the manufacturing process of the memory chips 60 are identical to those of the controller chips 30, explanations thereof are omitted.

A method of mounting the controller chip 30 on the wiring substrate 10 is explained next. The solder resist 16 serving as the first insulant is formed on the wiring substrate 10. A resin such as an epoxy resin, a phenol resin, a polyimide resin, a polyamide resin, an acrylic resin, a PBO resin, or a silicon resin, or a mixed material or a composite material thereof is used as the solder resist 16 serving as the first insulant. A filler such as silica may be included in the solder resist 16 serving as the first insulant.

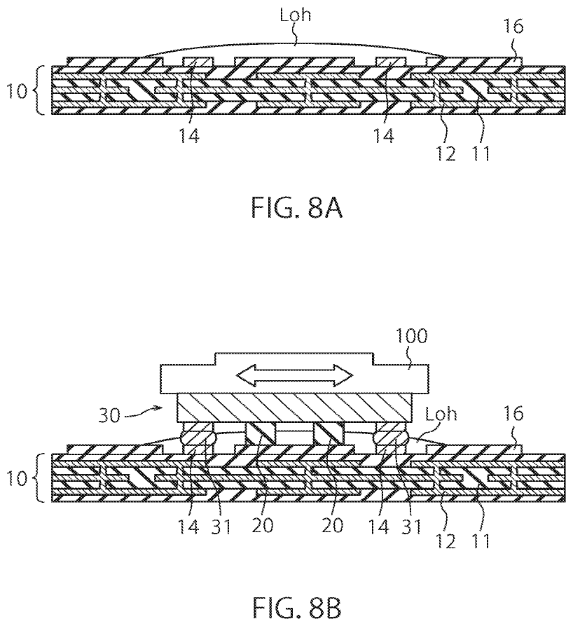

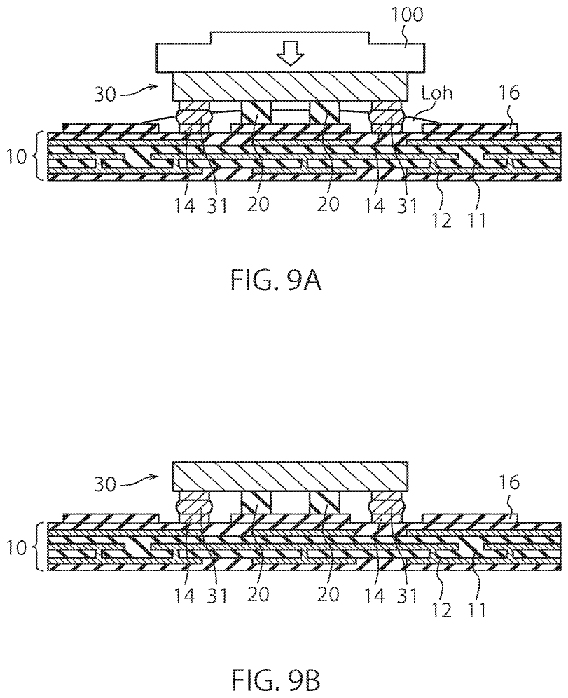

FIGS. 8A to 9B are sectional views illustrating an example of an assembly process for mounting the controller chip 30 on the wiring substrate 10. First, the wiring substrate 10 may be baked to remove water. Alternatively, plasma processing may be performed to enhance the adhesion between the wiring substrate 10 and the first adhesion layers 20.

Next, a material Loh having a hydroxy group is applied onto the wiring substrate 10 as illustrated in FIG. 8A. Pure water, alcohol, or the like may be used as the material Loh having a hydroxy group. The alcohol is at least one type selected from methanol, ethanol, isopropyl alcohol, polyvinyl alcohol, ethylene glycol, propylene glycol, diethylene glycol, glycerin, triethylene glycol, tetraethylene glycol, carbitol, cellosolve alcohol, and the like. The alcohol may alternatively be an alkyl ether material. Diethylene glycol monobutyl ether and triethylene glycol dimethyl ether are listed as examples. Alkane, an amine compound, and the like may also be used. For example, formamide and dimethylformamide may be listed. These may be used alone, or a plurality thereof may be mixed. An organic acid may be added to these materials. Examples of the organic acid are formic acid, acetic acid, benzoic acid, octanedioic acid, nonanedioic acid, decanedioic acid, dodecanedioic acid, tetradecanedioic acid, hexadecanedioic acid, heptadecanedioic acid, octadecanedioic acid, cyclohexanedicarboxylic acid, cycloheptanedicarboxylic acid, cyclooctanedicarboxylic acid, norbornanedicarboxylic acid, and adamantanedicarboxylic acid. The material Loh is applied by a method such as a dispensing method, a printing method, or a jet method. The material Loh having a hydroxy group is supplied to reduce and remove an oxide film (SnO, SnO₂) and the like on the surfaces of the metal bumps 31 and the metal pads 14.

Next, a pressure joining device 100 sucks the controller chip 30 and positions the controller chip 30 in such a manner that the metal bumps 31 correspond to the metal pads 14 of the wiring substrate 10 as illustrated in FIG. 8B. At this time, the material Loh having a hydroxy group may be in contact or without contact with the first adhesion layers 20.

Subsequently, the pressure joining device 100 applies pressure to the controller chip 30 and applies ultrasound while the metal bumps 31 are in contact with the corresponding metal pads 14. Accordingly, the metal bumps 31 are electrically connected to the metal pads 14 and the controller chip 30 is flip-chip connected onto the wiring substrate 10 as illustrated in FIG. 9A. At this time, the pressure joining device 100 may heat the metal bumps 31 and the metal pads 14. For example, the pressure joining device 100 heats the metal bumps 31 and the metal pads 14 at about 200° C. to soften the metal bumps 31 (for example, solder) and connects the metal bumps 31 and the metal pads 14 to each other also using ultrasound. Also using ultrasound in this way enables the metal bumps 31 to be rapidly connected to the metal pads 14. As a result, the throughput is improved. For example, an output of 5 watts is applied as the ultrasound. The amplitude is about 1 micrometer. The frequency of the ultrasound is 30 kHz to 200 kHz. While the example in which the ultrasound is also used is illustrated, the connection may be achieved only with heating. In a case of using only heating, the pressure joining device 100 heats the metal bumps 31 and the metal pads 14 at a temperature equal to or higher than the melting temperature of solder, for example, at about 250° C. to connect the metal bumps 31 and the metal pads 14 to each other.

The pressure joining device 100 further applies pressure to the controller chip 30 to bring the first adhesion layers 20 in contact with the solder resist 16 serving as the first insulant of the wiring substrate 10 and adhere the first adhesion layers 20 to the solder resist 16. The pressure joining device 100 may be a flip-chip bonder.

Next, the wiring substrate 10 is heated, for example, for one hour at 150° C. and the material Loh is vaporized as illustrated in FIG. 9B.

Thereafter, the spacers 50 are provided on the wiring substrate 10 and a plurality of memory chips 60 and a plurality of second adhesion layers (DAFs) 40 are alternately stacked on the controller chip 30. The back surfaces (the third surfaces) of the spacers 50 face the wiring substrate 10. The spacers 50 are provided around the first semiconductor chip. The spacers 50 are adhered to the wiring substrate 10 with a part of the adhesion layers 40 on the back surface of the spacers 50. The other second adhesion layers 40 are formed on top surfaces (the fourth surfaces) opposing to the third surfaces of the spacers 50 to adhere the memory chip 60 to the spacers 50.

For example, a second adhesion layer 40 is attached onto the second face F2 of the controller chip 30 and a memory chip 60 is placed on the second adhesion layer 40 to be adhered thereto. Alternatively, a second adhesion layer 40 is attached to the rear surface of a memory chip 60 and is adhered onto the second face F2 of the controller chip 30. Accordingly, the memory chip 60 can be pasted onto the controller chip 30. A plurality of second adhesion layers 40 and a plurality of memory chips 60 are further alternatively stacked on the controller chip 30. Thereafter, wiring bonding is performed as required and a structure including the controller chip 30 and the first adhesion layers 20 on the wiring substrate 10 is coated by the sealing resin 90, whereby the semiconductor device 1 illustrated in FIG. 1A is completed. The sealing resin 90 is characterized in being a molding resin. A resin such as an epoxy resin, a phenol resin, a polyimide resin, a polyamide resin, an acrylic resin, a PBO resin, or a silicon resin, or a mixed material or a composite material thereof is used as the molding resin. Examples of the epoxy resin are not particularly limited and a bisphenol epoxy resin such as a bisphenol A type, a bisphenol F type, a bisphenol AD type, or a bisphenol S type, a novolac epoxy resin such as a phenol novolac type or a cresol novolac type, a resorcinol epoxy resin, an aromatic epoxy resin such as trisphenol-methane triglycidyl ether, a naphthalene epoxy resin, a fluorene epoxy resin, a dicyclopentadiene epoxy resin, a polyether-modified epoxy resin, a benzophenone epoxy resin, an aniline epoxy resin, an NBR-modified epoxy resin, a CTBN-modified epoxy resin, and hydrogenated ones of these resins are listed as examples. Among these, the naphthalene epoxy resin and the dicyclopentadiene epoxy resin are preferable because being high in adhesion to Si. The benzophenone epoxy resin is also preferable because being likely to cure fast. These epoxy resins may be used alone or two or more types thereof may be used. A filler such as silica may be included in the sealing resin 90. The filler is preferably smaller than the gap between the controller chip 30 and the wiring substrate 10. The sealing resin 90 is formed using a molding device or the like. The thermal expansion coefficient of the molding resin as the sealing resin 90 is preferably smaller than that of the first adhesion layers 20. Accordingly, warp can be decreased, and fracture at connecting portions of the metal bumps during a reliability test can be suppressed because stress is reduced. The elastic modulus of the molding resin as the sealing resin 90 is preferably higher than that of the first adhesion layers 20. Accordingly, warp can be decreased, and fracture at the connecting portions of the metal bumps during the reliability test can be suppressed because stress is reduced.

When the controller chip 30 or the wiring substrate 10 is thinner, the controller chip 30 or the wiring substrate 10 is likely to warp and poor connection between the metal bumps 31 and the metal pads 14 is likely to occur. Further, the memory chips 60 become difficult to be stacked on the metal bumps 31 and the stacked memory chips 60 are likely to chip.

In contrast thereto, according to the present embodiment, the first adhesion layers 20 enable the controller chip 30 and the wiring substrate 10 to adhere to each other and reinforce connection between the metal bumps 31 and the metal pads 14 while straightening warp of the controller chip 30. Accordingly, the second face F2 of the controller chip 30 becomes close to a flat face and chip or poor connection of the memory chips 60 stacked above the controller chip 30 can be suppressed. Fracture of connection between the metal bumps 31 and the metal pads 14 can also be suppressed. For example, in a case in which the first adhesion layers 20 are provided as in the present embodiment, the connection between the metal bumps 31 and the metal pads 14 is maintained without fracturing even when the thickness of the controller chip 30 is in a range from 10 micrometers to 100 micrometers and the thickness of the wiring substrate 10 is in a range from 20 micrometers to 500 micrometers. When the thickness of the controller chip 30 is smaller than 100 micrometers, the controller chip 30 is likely to warp. However, according to the present embodiment, stable connection can be provided even when the controller chip 30 has warp. When the thickness of the wiring substrate 10 is smaller than 500 micrometers, the wiring substrate 10 is likely to warp. However, according to the present embodiment, stable connection can be provided even when the wiring substrate 10 has warp.

In a comparative example in which an underfill material is applied between the controller chip 30 and the wiring substrate 10, the underfill material crept up on the controller chip 30 and, when the memory chips 60 were stacked thereon, the memory chips 60 broke in some cases. However, because there is no resin creeping up on the controller chip 30 in the present embodiment, the memory chips 60 are less likely to break.

A temperature cycling test was performed on the semiconductor device 1 according to the present embodiment. A temperature cycling test is performed at −55° C. (30 minutes)-25° C. (5 minutes)-125° C. (30 minutes) as one cycle. As a result, no abnormality was confirmed at the connecting portions between the metal bumps 31 and the metal pads 14 in the semiconductor device 1 according to the present embodiment even after 3000 cycles.

Other electronic components may be mounted on the wiring substrate 10.

In the present embodiment, no NCP layer or NCF layer filling between the wiring substrate 10 and the controller chip 30 is provided and the first adhesion layers 20 are provided away from the connecting portions between the metal bumps 31 and the metal pads 14. Accordingly, the first adhesion layers 20 support the connection between the metal pads 14 and the metal bumps 31 and suppress fracture between the metal pads 14 and the metal bumps 31. Since no NCP or NCF is used, any resin or filler of NCP or NCF does not enter between the metal bumps 31 and the metal pads 14 and the connection between the metal bumps 31 and the metal pads 14 is maintained with a high reliability. The sealing resin 90 is filled in a region other than the first adhesion layers 20 between the wiring substrate 10 and the controller chip 30. Further, the same sealing resin 90 is located also around the memory chips 60. Accordingly, the thermal expansion coefficient difference between the periphery of the controller chip 30 and the memory chips 60 and the periphery of the metal bumps 31 is small and warp of the controller chip 30 and the memory chips 60 is suppressed.

### First Modification

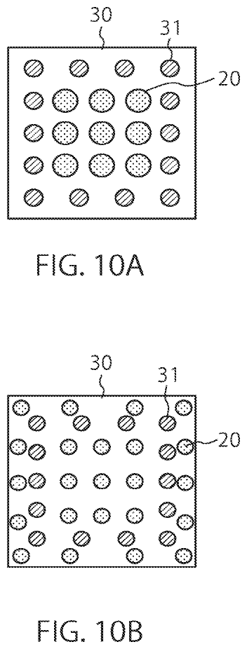

FIGS. 10A and 10B are plan views illustrating a layout of the metal bumps 31 and the first adhesion layers 20 on the second face F2 of the controller chip 30. As illustrated in FIG. 10A, the first adhesion layers 20 may be two-dimensionally arranged in a matrix inside a region surrounded by the metal bumps 31 while being separated from the metal bumps 31. The distances between the metal bumps 31 and the first adhesion layers 20 are, for example, in a range from 10 micrometers to 1 millimeter. If the distances between the metal bumps 31 and the first adhesion layers 20 are shorter than 10 micrometers, the first adhesion layers 20 have a risk of being distorted or deformed at the time of exposure and development of the first adhesion layers 20. On the other hand, if the distances between the metal bumps 31 and the first adhesion layers 20 exceed 1 millimeter, the warp of the controller chip 30 is not straightened and there is a risk that the first adhesion layers 20 are peeled off.

The adhesion area of the first adhesion layers 20 may be larger than the contact area between the metal bumps 31 and the metal pads 14. This can reinforce more the connection between the metal bumps 31 and the metal pads 14. Further, the warp of the controller chip 30 can be straightened.

As illustrated in FIG. 10B, the first adhesion layers 20 may be provided substantially uniformly inside and outside the region surrounded by the metal bumps 31. With the first adhesion layers 20 thus provided around the metal bumps 31, the entire controller chip 30 can be adhered to the wiring substrate 10 and the warp of the controller chip 30 can be straightened more.

### Second Modification

In a case in which the controller chip 30 and the wiring substrate 10 are stacked after the material Loh having a hydroxy group is supplied onto the wiring substrate 10, the first adhesion layers 20 sometimes do not adhere to the wiring substrate 10.

In order to address this problem, in a second modification, after the controller chip 30 and the wiring substrate 10 are connected, the material Loh having a hydroxy group is baked in an oven for vaporization. Thereafter, the controller chip 30 is pressurized and heated by the pressure joining device, and the controller chip 30 and the wiring substrate 10 are adhered to each other with the first adhesion layers 20. Other parts of the process of the second modification may be identical to corresponding ones of the first embodiment.

The material Loh having a hydroxy group may be input in a liquid state near the metal bumps 31 after the controller chip 30 and the wiring substrate 10 are adhered to each other. Also in this case, by subsequently pressurizing and heating with the pressure joining device, the metal bumps 31 can be pressured-joined to the metal pads 14 while an oxide film is removed by the material Loh. At this time, ultrasound may also be used.

### Third Modification

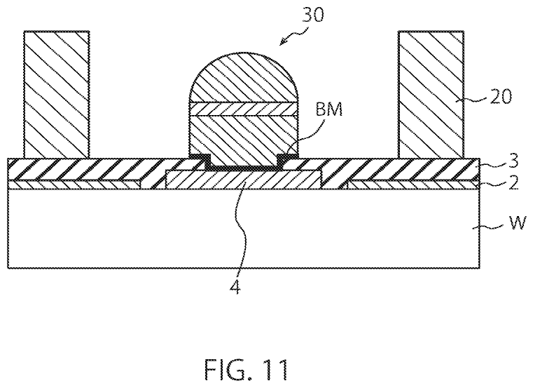

As illustrated in FIG. 6B, the height of the first adhesion layers 20 can be lower than the height of the metal bumps 31 at the time of formation of the controller chip 30. However, the height of the first adhesion layers 20 may be equal to or higher than the height of the metal bumps 31 as illustrated in FIG. 11. FIG. 11 is a sectional view illustrating a configuration example of the controller chip 30 according to a third modification.

In the case in which the height of the first adhesion layers 20 is equal to or higher than that of the metal bumps 31 as in the third modification, the first adhesion layers 20 are brought into contact with the wiring substrate 10 earlier than the metal bumps 31 at the time of mounting of the controller chip 30 on the wiring substrate 10, and the metal bumps 31 are connected to the metal pads 14 after the first adhesion layers 20 are sufficiently adhered to the wiring substrate 10. Even with this configuration, effects of the present embodiment can be achieved.

1. A semiconductor device comprising:
a wiring substrate comprising pads electrically connected to wires provided on an insulating substrate, and a first insulant provided between the pads;
a first semiconductor chip comprising metal bumps respectively connected to the pads on the wiring substrate on a first face facing the wiring substrate;
a first adhesion layer provided between the first insulant and the first semiconductor chip and adhering the wiring substrate and the first semiconductor chip to each other; and
an insulating resin covering peripheries of the first adhesion layer and the metal bumps between the wiring substrate and the first semiconductor chip, and a structure on the wiring substrate.

2. The device of claim 1, wherein the first adhesion layer has a thermal expansion coefficient larger than those of the wiring substrate and the first semiconductor chip.

3. The device of claim 1, wherein the first adhesion layer has an elastic modulus lower than those of the first insulant and the metal bumps.

4. The device of claim 2, wherein the first adhesion layer has an elastic modulus lower than those of the first insulant and the metal bumps.

5. The device of claim 1, wherein the first adhesion layer is placed away from the metal bumps.

6. The device of claim 1, wherein the first adhesion layer has an adhesive area larger than a contact area between the metal bumps and the pads.

7. The device of claim 1, further comprising:
a second adhesion layer provided on a second face of the first semiconductor chip on an opposite side to the first face; and
a second semiconductor chip provided on the second adhesion layer.

8. The device of claim 7, wherein
the first semiconductor chip is a controller chip configured to control the second semiconductor chip, and
the second semiconductor chip is a memory chip.

9. The device of claim 7, wherein a plurality of the second semiconductor chips and a plurality of the second adhesion layers are alternately stacked above the first semiconductor chip.

10. The device of claim 7 further comprising:
a support member having a third surface facing the wiring substrate and a fourth surface opposing to the third surface, the support member being provided around the first semiconductor chip, wherein
the second adhesion layers are provided on the fourth surface.

11. A manufacturing method of a semiconductor device, the method comprising:
applying a photosensitive first adhesion layer on a first face of a first semiconductor chip comprising metal bumps;
selectively leaving the first adhesion layer at predetermined positions on the first face;
connecting the metal bumps of the first semiconductor chip and pads of a wiring substrate to each other and adhering the first adhesion layer to a first insulant of the wiring substrate; and
forming an insulating resin coating the first semiconductor chip on the wiring substrate, the first adhesion layer, and a structure on the wiring substrate.

12. The method of claim 11, wherein the first adhesion layer has a thermal expansion coefficient larger than those of the wiring substrate and the first semiconductor chip.

13. The method of claim 11, wherein the first adhesion layer has an elastic modulus lower than those of the first insulant and the metal bumps.

14. The method of claim 12, wherein the first adhesion layer has an elastic modulus lower than those of the first insulant and the metal bumps.

15. The method of claim 11, comprising applying a material having a hydroxy group onto the wiring substrate.

16. The method of claim 11, comprising applying ultrasound when connecting the metal bumps of the first semiconductor chip and the pads of the wiring substrate to each other.

17. The method of claim 11, further comprising:
forming a second adhesion layer on a second face of the first semiconductor chip on an opposite side to the first face; and
attaching a second semiconductor chip onto the second adhesion layer.

18. The method of claim 17, wherein
the first semiconductor chip is a controller chip configured to control the second semiconductor chip, and
the second semiconductor chip is a memory chip.

19. The method of claim 17, wherein a plurality of the second semiconductor chips and a plurality of the second adhesion layers are alternately stacked above the first semiconductor chip.

20. The method of claim 17 further comprising:
providing a support member having a third surface facing the wiring substrate, the support member being provided around the first semiconductor chip; and
forming second adhesion layers on a fourth surface of the support member opposing to the third surface.
